(19) United States
(12) Patent Application Publication
(10) Pub. No.: US 2024/0297049 A1
(43) Pub. Date: Sep. 5, 2024

(54) High Oxide Removal Rates Shallow Trench Isolation Chemical Mechanical Planarization Compositions

(71) Applicant: Versum Materials US, LLC, Tempe, AZ (US)

(72) Inventors: Joseph D. Rose, Gilbert, AZ (US); Hongjun Zhou, Chandler, AZ (US); Xiaobo Shi, Chandler, AZ (US); Krishna P. Murella, Phoenix, AZ (US)

(73) Assignee: Versum Materials US, LLC, Tempe, AZ (US)

(21) Appl. No.: 17/754,771

(22) PCT Filed: Oct. 21, 2020
(86) PCT No.: PCT/US2020/056677

§ 371 Date: Apr. 12, 2022

Related U.S. Application Data
(60) Provisional application No. 62/925,378, filed on Oct. 24, 2019.

(30) Foreign Application Priority Data
Oct. 13, 2020 (TW) 109135360

(51) Int. Cl. H01L 21/3105; B24B 7/22; C09G 1/02

(52) U.S. Cl. CPC H01L 21/31053; C09G 1/02; B24B 7/228

(57) ABSTRACT

Present invention provides Chemical Mechanical Planarization Polishing (CMP) compositions for Shallow Trench Isolation (STI) applications. The CMP compositions 5 contain ceria coated inorganic oxide particles as abrasives, such as ceria-coated silica particles; chemical additive selected from the group consisting of nitrogen containing organic aromatic or pyridine ring molecule with one carboxylic acid group, one carboxy late salt group, or one carboxy late ester group at position −2, −3, or −4 respectively; non-ionic organic molecule with multi hydroxyl functional groups; and 10 combinations thereof; water soluble solvent; and optionally biocide and pH adjuster; wherein the composition has a pH of 2 to 12, preferably 3 to 10, and more preferably 4 to 9.

### CROSS REFERENCE TO RELATED PATENT APPLICATIONS

This application claims the benefit of priority under 35 U.S.C. § 119(e) to earlier filed U.S. patent application Ser. Nos. 62/925,378 filed on Oct. 24, 2019, which is entirely incorporated herein by reference.

### BACKGROUND OF THE INVENTION

This invention relates to the Shallow Trench Isolation (STI) chemical mechanical planarization (CMP) compositions and chemical mechanical planarization (CMP) for Shallow Trench Isolation (STI) process.

In the fabrication of microelectronics devices, an important step involved is polishing, especially surfaces for chemical-mechanical polishing for recovering a selected material and/or planarizing the structure.

For example, a SiN layer is deposited under a SiO₂ layer to serve as a polish stop layer. The role of such polish stop is particularly important in Shallow Trench Isolation (STI) structures. Selectivity is characteristically expressed as the ratio of the oxide polish rate to the nitride polish rate. An example is an increased polishing selectivity rate of silicon dioxide (SiO₂) as compared to silicon nitride (SiN).

In the global planarization of patterned STI structures, reducing oxide trench dishing is a key factor to be considered. The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

U.S. Pat. No. 5,876,490 discloses the polishing compositions containing abrasive particles and exhibiting normal stress effects. The slurry further contains non-polishing particles resulting in reduced polishing rate at recesses, while the abrasive particles maintain high polish rates at elevations. This leads to improved planarization. More specifically, the slurry comprises cerium oxide particles and polymeric electrolyte, and can be used for Shallow Trench Isolation (STI) polishing applications.

U.S. Pat. No. 6,964,923 teaches the polishing compositions containing cerium oxide particles and polymeric electrolyte for Shallow Trench Isolation (STI) polishing applications. Polymeric electrolyte being used includes the salts of polyacrylic acid, similar as those in U.S. Pat. No. 5,876,490. Ceria, alumina, silica & zirconia are used as abrasives. Molecular weight for such listed polyelectrolyte is from 300 to 20,000, but in overall, <100,000.

U.S. Pat. No. 6,616,514 discloses a chemical mechanical polishing slurry for use in removing a first substance from a surface of an article in preference to silicon nitride by chemical mechanical polishing. The chemical mechanical polishing slurry according to the invention includes an abrasive, an aqueous medium, and an organic polyol that does not dissociate protons, said organic polyol including a compound having at least three hydroxyl groups that are not dissociable in the aqueous medium, or a polymer formed from at least one monomer having at least three hydroxyl groups that are not dissociable in the aqueous medium.

However, those prior disclosed Shallow Trench Isolation (STI) polishing compositions did not address the importance of oxide trench dishing reducing and more uniform oxide trench dishing on the polished patterned wafers along with the high oxide vs nitride selectivity.

Also, those prior disclosed Shallow Trench Isolation (STI) polishing compositions did not address the effective removal of step-height on some oxide films, such as HDP, on the patterned wafers.

Therefore, it should be readily apparent from the foregoing that there remains a need within the art for compositions, methods and systems of STI chemical mechanical polishing that can afford the reduced oxide trench dishing and more uniformed oxide trench dishing across various sized oxide trench features on polishing patterned wafers in a STI chemical and mechanical polishing (CMP) process, and effectively remove the step-height of certain types of oxide films on polishing patterned wafers, in addition to high removal rate of silicon dioxide as well as high selectivity for silicon dioxide to silicon nitride.

### SUMMARY OF THE INVENTION

The present invention provides for a reduced oxide trench dishing and more uniformed oxide trench dishing across various sized oxide trench features on the polished patterned wafers and effectively remove the step-height of certain types of oxide films on polishing patterned wafers, in addition to high removal rate of silicon dioxide as well as high selectivity for silicon dioxide to silicon nitride.

The present invented STI CMP polishing compositions also provides high oxide vs nitride selectivity by introducing chemical additives as SiN film removal rate suppressing agents and oxide trenching dishing reducers in the Chemical mechanical polishing (CMP) compositions for Shallow Trench Isolation (STI) CMP applications at wide pH range including acidic, neutral and alkaline pH conditions.

The disclosed chemical mechanical polishing (CMP) composition for Shallow Trench Isolation (STI) CMP applications have a unique combination of using ceria-coated inorganic oxide abrasive particles and the suitable chemical additives as oxide trench dishing reducing agents and nitride suppressing agents.

In one aspect, there is provided a STI CMP polishing composition comprises:
ceria-coated inorganic oxide particles;
chemical additive selected from the group consisting of nitrogen containing organic aromatic or pyridine ring molecule with one carboxylic acid group, one carboxylate salt group, or carboxylate ester group; organic molecule with multi hydroxyl functional groups; and combinations thereof;
a water soluble solvent; and
optionally
biocide; and
pH adjuster;
wherein the composition has a pH of 2 to 12, preferably 3 to 10, more preferably 4 to 9, and most preferably 4.5 to 7.5.

In another aspect, there is provided a STI CMP polishing composition comprises:
ceria-coated inorganic oxide particles;
nitrogen containing organic aromatic or pyridine ring molecule with one carboxylic acid group, one carboxylate salt group, or one carboxylate ester group;
non-ionic organic molecule with multi hydroxyl functional groups;
water soluble solvent; and
optionally
biocide; and
pH adjuster;
wherein
the nitrogen containing organic aromatic or pyridine ring molecule with one carboxylic acid group, one carboxylate salt group, or one carboxylate ester group has a general molecular structure of:

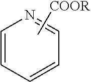

wherein R can be hydrogen atom, a positive metal ion, or an alkyl group CₙH₂ₙ₊₁, n is from 1 to 12, preferably 1 to 6, and more preferably 1 to 3;
and
the composition has a pH of 2 to 12, preferably 3 to 10, and more preferably 4 to 9, and most preferably 4.5 to 7.5.

The ceria-coated inorganic oxide particles include, but are not limited to, ceria-coated colloidal silica, ceria-coated high purity colloidal silica, ceria-coated alumina, ceria-coated titania, ceria-coated zirconia, or any other ceria-coated inorganic metal oxide particles.

The water soluble solvent includes but is not limited to deionized (DI) water, distilled water, and alcoholic organic solvents.

The chemical additive functions as a SiN film removal rate suppressing agent and oxide trenching dishing reducer.

The general molecular structure for the chemical additives which are nitrogen containing organic aromatic or pyridine ring molecule with one carboxylic acid group, one carboxylate salt group, or one carboxylate ester group is shown below:

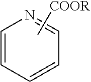

In the general molecular structure, —COOR group can be attached to the carbon atom positioned at −2, −3, or 4 in the ring as shown below:

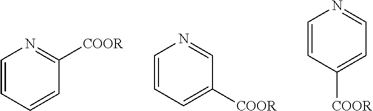

Where, R can be hydrogen atom, a positive metal ion, and an alkyl group CₙH₂ₙ₊₁, n is from 1 to 12, preferably 1 to 6, and more preferably 1 to 3.

The following 3 chemical additives are nitrogen containing organic aromatic or pyridine ring molecule with one carboxylic acid group when R is hydrogen atom:

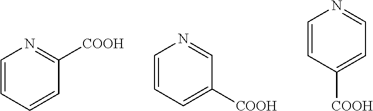 [SMILES: O=C(O)c1ccccn1 ; O=C(O)c1cccnc1 ; O=C(O)c1ccncc1]

2-Picolinic Acid 3-Pyridinrcarboxylic Acid 4-Pyridinrcarboxylic Acid

When R is a positive metal ion, the following general molecular structure is shown:

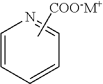

In which, the positive ions can be sodium, potassium or ammonium ion.

When R group is an alkyl group CₙH₂ₙ₊₁, n is from 1 to 12, preferably 1 to 6, and more preferably 1 to 3; the chemical additives are pyridine carboxylate esters.

One of the general molecular structure for the chemical additives that are organic molecular with multi hydroxyl functional groups is shown below:

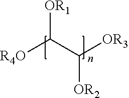

In the general molecular structure, n is selected from 1 to 5,000, preferably from 2 to 12, and more preferably from 3 to 6.

In these general molecular structures; R1, R2, R3, and R4 groups can be the same or different atoms or functional groups.

R1, R2, R3, and R4 can be independently selected from the group consisting of hydrogen, an alkyl group CₙH₂ₙ₊₁, n is from 1 to 12, preferably 1 to 6, and more preferably 1 to 3, alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least two or more, preferably four or more, are hydrogen atoms.

When R1, R2, R3 and R4 are all hydrogen atoms, the chemical additive bear multi hydroxyl functional groups. The molecular structures of some examples of such chemical additives are listed below:

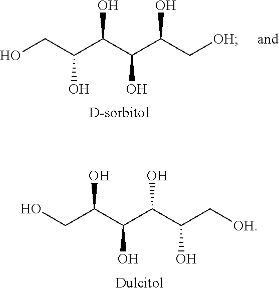 [SMILES: OC[C@@H](O)[C@@H](O)[C@H](O)[C@@H](O)CO ; OC[C@@H](O)[C@H](O)[C@H](O)[C@@H](O)CO]

Another general molecular structure for the chemical additives that are organic molecular with multi hydroxyl functional groups is shown below:

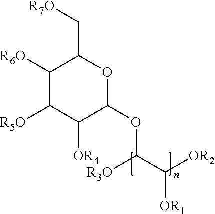

In these general molecular structures; R1, R2, R3, R4, R5, R6, and R7 of R groups can be the same or different atoms or functional groups.

In the general molecular structures, n is selected from 1 to 5,000, preferably from 1 to 100, more preferably from 1 to 12, and most preferably from 2 to 6

Each of the R groups can be independently selected from the group consisting of hydrogen, alkyl group CₙH₂ₙ₊₁, n is from 1 to 12, preferably 1 to 6, and more preferably 1 to 3, alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least two or more, preferably four or more, more preferably six or more of them are hydrogen atoms.

When R1, R2, R3 R4, R5, R6, and R7 are all hydrogen atoms which provide a chemical additive bearing multi hydroxyl functional groups.

The molecular structures of some examples of such chemical additives are listed below:

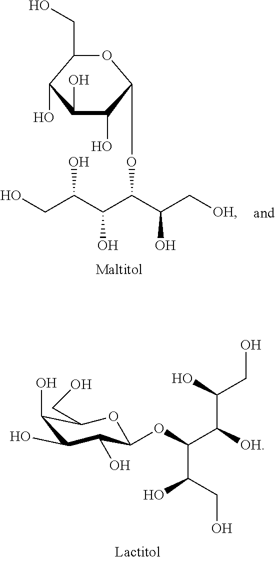

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished oxide films can be Chemical vapor deposition (CVD), Plasma Enhance CVD (PECVD), High Density Deposition CVD (HDP), or spin on oxide films.

The substrate disclosed above can further comprises a silicon nitride surface. The removal selectivity of SiO₂:SiN is greater than silicon nitride is greater than 10, preferably greater than 30, and more preferably greater than 50.

### BRIEF DESCRIPTION OF SEVERAL VIEWS OF THE DRAWINGS

FIG. 1. Effects of Picolinic Acid on Blanket Film and P50 μm RR (Å/min.)

FIG. 2. Effects of Picolinic Acid on Film RR (A/min.) & TEOS:SiN Selectivity FIG. 3. Effects of Picolinic Acid on Oxide Trench Dishing Rate etc.

FIG. 4. Effects of Picolinic Acid on Film RR (A/min.)

FIG. 5. Effects of Picolinic Acid at Different pH on Film RR (A/min.) & TEOS:SiN Selectivity

FIG. 6. Effects of Picolinic Acid at Different pH on Oxide Trench Loss (A/sec.)

FIG. 7. Effects of Picolinic Acid at Different pH on Oxide Trench Dishing Rate (A/sec.)

### DETAILED DESCRIPTION OF THE INVENTION

In the global planarization of patterned STI structures, suppressing SiN removal rates and reducing oxide trench dishing and providing more uniform oxide trench dishing across various sized oxide trench features are key factors to be considered. The lower trench oxide loss will prevent electrical current leaking between adjacent transistors. Non-uniform trench oxide loss across die (within Die) will affect transistor performance and device fabrication yields. Severe trench oxide loss (high oxide trench dishing) will cause poor isolation of transistor resulting in device failure. Therefore, it is important to reduce trench oxide loss by reducing oxide trench dishing in STI CMP polishing compositions.

This invention relates to the Chemical mechanical polishing (CMP) compositions for Shallow Trench Isolation (STI) CMP applications.

More specifically, the disclosed chemical mechanical polishing (CMP) composition for Shallow Trench Isolation (STI) CMP applications have a unique combination of using ceria-coated inorganic oxide abrasive particles and the suitable chemical additives as oxide trench dishing reducing agents and nitride suppressing agents.

The suitable chemical additives include but are not limited to two types of chemical additives and the combinations thereof: —first type of chemical additives are nitrogen containing organic aromatic or pyridine ring molecule with one carboxylic acid group, carboxylate salt group, or—carboxylate ester group; and second type of chemical additives are organic molecule with multi hydroxyl functional groups.

The first type of chemical additives are nitrogen containing organic aromatic or pyridine ring molecule with one carboxylic acid group, one carboxylate salt group, or one carboxylate ester group. These carboxylic acid group, carboxylate salt group, or carboxylate ester group can be attached to the carbon atom positioned at −2, −3, or 4 in the ring respectively.

The second type of chemical additives are non-ionic and non-aromatic organic molecules which bearing two or more, i.e. multi hydroxyl functional groups.

The chemical additives provide the benefits of achieving high oxide film removal rates, low SiN film removal rates, high and tunable Oxide:SiN selectivity, and more importantly, providing desirable step-height removal rates while polishing patterned wafers and significantly reducing oxide trench dishing and improving over polishing window stability on polishing patterned wafers.

In one aspect, there is provided a STI CMP composition comprises:
ceria-coated inorganic oxide particles;
chemical additive selected from the group consisting of nitrogen containing organic aromatic or pyridine ring molecule with one carboxylic acid group, one carboxylate salt group, or one carboxylate ester group; organic molecule with multi hydroxyl functional groups; and combinations thereof;
a water soluble solvent; and
optionally
biocide; and
pH adjuster;
wherein the composition has a pH of 2 to 12, preferably 3 to 10, more preferably 4 to 9, and most preferably 4.5 to 7.5.

In another aspect, there is provided a STI CMP polishing composition comprises:
ceria-coated inorganic oxide particles;
nitrogen containing organic aromatic or pyridine ring molecule with one carboxylic acid group, one carboxylate salt group, or one carboxylate ester group;
non-ionic organic molecule with multi hydroxyl functional groups;
water soluble solvent; and
optionally
biocide; and
pH adjuster;
wherein
the nitrogen containing organic aromatic or pyridine ring molecule with one carboxylic acid group, one carboxylate salt group, or one carboxylate ester group has a general molecular structure of:

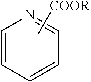

wherein R can be hydrogen atom, a positive metal ion, or an alkyl group CₙH₂ₙ₊₁, n is from 1 to 12, preferably 1 to 6, and more preferably 1 to 3;
and
the composition has a pH of 2 to 12, preferably 3 to 10, and more preferably 4 to 9, and most preferably 4.5 to 7.5.

The ceria-coated inorganic oxide particles include, but are not limited to, ceria-coated colloidal silica, ceria-coated high purity colloidal silica, ceria-coated alumina, ceria-coated titania, ceria-coated zirconia, or any other ceria-coated inorganic metal oxide particles.

The particle sizes of these ceria-coated inorganic oxide particles in the disclosed invention herein are ranged from 10 nm to 1,000 nm, the preferred mean particle sized are ranged from 20 nm to 500 nm, the more preferred mean particle sizes are ranged from 50 nm to 250 nm.

The concentrations of these ceria-coated inorganic oxide particles range from 0.01 wt. % to 20 wt. %, the preferred concentrations range from 0.05 wt. % to 10 wt. %, the more preferred concentrations range from 0.1 wt. % to 5 wt. %.

The preferred ceria-coated inorganic oxide particles are ceria-coated colloidal silica particles.

The water soluble solvent includes but is not limited to deionized (DI) water, distilled water, and alcoholic organic solvents.

The preferred water soluble solvent is DI water.

The STI CMP composition may contain biocide from 0.0001 wt. % to 0.05 wt. %; preferably from 0.0005 wt. % to 0.025 wt. %, and more preferably from 0.001 wt. % to 0.01 wt. %.

The biocide includes, but is not limited to, Kathon™, Kathon™ CG/ICP II, from Dupont/Dow Chemical Co. Bioban from Dupont/Dow Chemical Co. They have active ingredients of 5-chloro-2-methyl-4-isothiazolin-3-one and 2-methyl-4-isothiazolin-3-one.

The STI CMP composition may contain a pH adjuster.

An acidic or basic pH adjuster can be used to adjust the STI CMP compositions to the optimized pH value.

The pH adjusters include, but are not limited to nitric acid, hydrochloric acid, sulfuric acid, phosphoric acid, other inorganic or organic acids, and mixtures thereof.

pH adjusters also include the basic pH adjusters, such as sodium hydride, potassium hydroxide, ammonium hydroxide, tetraalkyl ammonium hydroxide, organic quaternary ammonium hydroxide compounds, organic amines, and other chemical reagents that can be used to adjust pH towards the more alkaline direction.

The STI CMP composition contains 0 wt. % to 1 wt. %; preferably 0.01 wt. % to 0.5 wt. %; more preferably 0.1 wt. % to 0.25 wt. % pH adjuster.

The STI CMP composition contains 0.0001 wt. % to 2.0% wt. %, 0.0002 wt. % to 1.0 wt. %, or 0.0005 wt. % to 0.5 wt. % chemical additives which are nitrogen containing organic aromatic or pyridine ring molecule with one carboxylic acid group, one carboxylate salt group, or one carboxylate ester group.

The STI CMP composition contains 0.0001 wt. % to 2.0% wt. %, 0.001 wt. % to 1.0 wt. %, or 0.005 wt. % to 0.75 wt. % chemical additives that are organic molecular with multi hydroxyl functional groups.

The general molecular structure for the chemical additives which are nitrogen containing organic aromatic or pyridine ring molecule with one carboxylic acid group, one carboxylate salt group, or one carboxylate ester group is shown below:

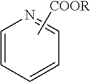

In the general molecular structure, —COOR group can be attached to the carbon atom positioned at −2, −3, or 4 in the ring as shown below:

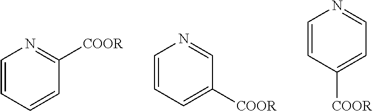

Where, R can be hydrogen atom, a positive metal ion, and an alkyl group CₙH₂ₙ₊₁, n is from 1 to 12, preferably 1 to 6, and more preferably 1 to 3.

When R is hydrogen atom, the chemical additives are nitrogen containing organic aromatic or pyridine ring molecule with one carboxylic acid group as listed below:

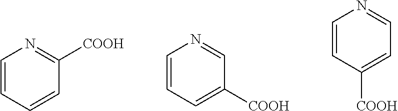 [SMILES: O=C(O)c1ccccn1 ; O=C(O)c1cccnc1 ; O=C(O)c1ccncc1]

2-Picolinic Acid 3-Pyridinrcarboxylic Acid 4-Pyridinrcarboxylic Acid

When R is a positive metal ion, the following general molecular structure is shown:

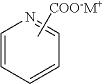

In which, the positive ions can be sodium, potassium or ammonium ion.

When R group is an alkyl group CₙH₂ₙ₊₁, n is from 1 to 12, preferably 1 to 6, and more preferably 1 to 3; and the chemical additives are pyridine carboxylate esters.

One of the general molecular structure for the type 2 chemical additives that are organic molecular with multi hydroxyl functional groups is shown below:

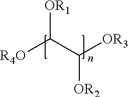

In the general molecular structure, n is selected from 1 to 5,000, preferably from 2 to 12, and more preferably from 3 to 6.

In these general molecular structures; R1, R2, R3, and R4 groups can be the same or different atoms or functional groups.

R1, R2, R3, and R4 can be independently selected from the group consisting of hydrogen, alkyl CₙH₂ₙ₊₁, n is from 1 to 12, preferably 1 to 6, and more preferably 1 to 3; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least two or more, preferably four or more, are hydrogen atoms.

When R1, R2, R3 and R4 are all hydrogen atoms, the chemical additive bear multi hydroxyl functional groups. The molecular structures of some examples of such chemical additives are listed below:

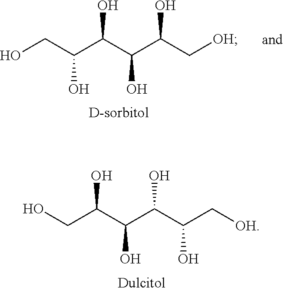 [SMILES: OC[C@@H](O)[C@@H](O)[C@H](O)[C@@H](O)CO ; OC[C@@H](O)[C@H](O)[C@H](O)[C@@H](O)CO]

Another general molecular structure for the type 2 chemical additives with multi hydroxyl functional groups is shown below:

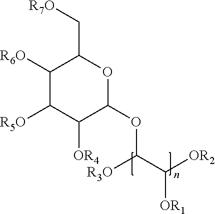

In these general molecular structures; R1, R2, R3, R4, R5, R6, and R7 of R groups can be the same or different atoms or functional groups.

In the general molecular structures, n is selected from 1 to 5,000, preferably from 1 to 100, more preferably from 1 to 12, and most preferably from 2 to 6

Each of the R groups can be independently selected from the group consisting of hydrogen, alkyl (CₙH₂ₙ₊₁, n is from 1 to 12, preferably 1 to 6, and more preferably 1 to 3), alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least two or more, preferably four or more, more preferably six or more of them are hydrogen atoms.

When R1, R2, R3 R4, R5, R6, and R7 are all hydrogen atoms which provide a chemical additive bearing multi hydroxyl functional groups.

The molecular structures of some examples of such chemical additives are listed below:

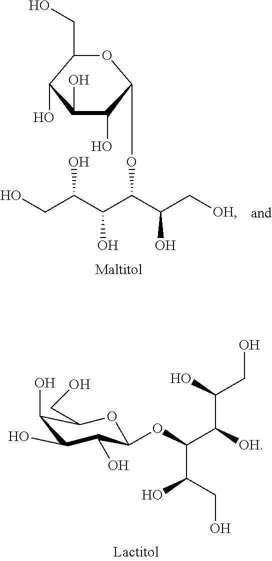

In another aspect, there is provided a method of chemical mechanical polishing (CMP) a substrate having at least one surface comprising silicon dioxide using the chemical mechanical polishing (CMP) composition described above in Shallow Trench Isolation (STI) process.

In another aspect, there is provided a system of chemical mechanical polishing (CMP) a substrate having at least one surface comprising silicon dioxide using the chemical mechanical polishing (CMP) composition described above in Shallow Trench Isolation (STI) process.

The polished oxide films can be Chemical vapor deposition (CVD), Plasma Enhance CVD (PECVD), High Density Deposition CVD (HDP), or spin on oxide films.

The substrate disclosed above can further comprises a silicon nitride surface. The removal selectivity of SiO₂:SiN is greater than 10, preferably greater than 20, and more preferably greater than 30.

In another aspect, there is provided a method of chemical mechanical polishing (CMP) a substrate having at least one surface comprising silicon dioxide using the chemical mechanical polishing (CMP) composition described above in Shallow Trench Isolation (STI) process. The polished oxide films can be CVD oxide, PECVD oxide, High density oxide, or Spin on oxide films.

The following non-limiting examples are presented to further illustrate the present invention.

### CMP Methodology

In the examples presented below, CMP experiments were run using the procedures and experimental conditions given below.

### Glossary

### Components

Ceria-coated Silica: used as abrasive having a particle size of approximately 100 nanometers (nm); such ceria-coated silica particles can have a particle size of ranged from approximately 20 nanometers (nm) to 500 nanometers (nm);

Ceria-coated Silica particles (with varied sizes) were supplied by JGCC Inc. in Japan.

Chemical additives, such as picolinic acid, maltitol, D-Fructose, Dulcitol, D-sorbitol and other chemical raw materials were supplied by Sigma-Aldrich, St. Louis, MO
TEOS: tetraethyl orthosilicate
Polishing Pad: Polishing pad, IC 1000, IC1010 and other pads were used during CMP, supplied by DOW, Inc.

### Parameters

### General

Å or A: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: composition flow, ml/min
Wt. % or %: weight percentage (of a listed component)
TEOS:SiN Selectivity: (removal rate of TEOS)/(removal rate of SiN)
HDP: high density plasma deposited TEOS
TEOS or HDP Removal Rates: Measured TEOS or HDP removal rate at a given down pressure. The down pressure of the CMP tool was 2.0, 3.0 or 4.0 psi in the examples listed above.
SiN Removal Rates: Measured SiN removal rate at a given down pressure. The down pressure of the CMP tool was 3.0 psi in the examples listed.

### Metrology

Films were measured with a ResMap CDE, model 168, manufactured by Creative Design Engineering, Inc, 20565 Alves Dr., Cupertino, CA, 95014. The ResMap tool is a four-point probe sheet resistance tool. Forty-nine-point diameter scan at 5 mm edge exclusion for film was taken.

### CMP Tool

The CMP tool that was used is a 200 mm Mirra, or 300 mm Reflexion manufactured by Applied Materials, 3050 Boweres Avenue, Santa Clara, California, 95054. An IC1000 pad supplied by DOW, Inc, 451 Bellevue Rd., Newark, DE 19713 was used on platen 1 for blanket and pattern wafer studies.

The IC1010 pad or other pad was broken in by conditioning the pad for 18 mins. At 7 lbs. down force on the conditioner. To qualify the tool settings and the pad break-in two tungsten monitors and two TEOS monitors were polished with Versum® STI2305 composition, supplied by Versum Materials Inc. at baseline conditions.

### Wafers

Polishing experiments were conducted using PECVD or LECVD or HD TEOS wafers. These blanket wafers were purchased from Silicon Valley Microelectronics, 2985 Kifer Rd., Santa Clara, CA 95051.

### Polishing Experiments

In blanket wafer studies, oxide blanket wafers, and SiN blanket wafers were polished at baseline conditions. The tool baseline conditions were: table speed; 87 rpm, head speed: 93 rpm, membrane pressure; 2.0 psi, inter-tube pressure; 2.0 psi, retaining ring pressure; 2.9 psi, composition flow; 200 ml/min.

The composition was used in polishing experiments on patterned wafers (MIT860), supplied by SWK Associates, Inc. 2920 Scott Blvd. Santa Clara, CA 95054). These wafers were measured on the Veeco VX300 profiler/AFM instrument. The 3 different sized pitch structures were used for oxide dishing measurement. The wafer was measured at center, middle, and edge die positions.

TEOS:SiN Selectivity: (removal rate of TEOS)/(removal rate of SiN) obtained from the STI CMP polishing compositions were tunable.

### WORKING EXAMPLES

In the following working examples, a STI P1 (STI P1 step is to remove the overburden oxide films in relative high removal rates) polishing composition comprising 1.0 wt. % cerium-coated silica particles, 0.1 wt. % D-sorbitol, a biocide ranging from 0.0001 wt. % to 0.05 wt. %, and deionized water was prepared as reference (ref.).

The polishing compositions were prepared with the reference (1.0 wt. % cerium-coated silica, a biocide ranging from 0.0001 wt. % to 0.05 wt. %, and deionized water) and a disclosed chemical additive in the range of 0.0025 wt. % to 0.28% wt. %.

Tables in the examples had % as wt. %, and ppm as ppm by weight.

### Example 1

In Example 1, the polishing compositions used for oxide P1 step polishing were shown in Table 1. The reference sample was made using 1.0 wt. % ceria-coated silica plus very low concentration of biocide and 0.1 wt. % D-sorbitol. The second chemical additive picolinic acid was used at 0.002 wt. % and 0.02 wt. % respectively in the testing samples.

All reference sample and testing samples had same pH values at around 5.35.

TABLE 1
Effects of Picolinic Acid on Blanket Film and P50 μm RR (Å/min.)

| | | P50 Active | P50 Trench |
|---|---|---|---|
| | HDP RR | Oxide RR | Oxide RR |
| Compositions | (A/min.) | (A/min.) | (A/min.) |
| 1.0% Ceria-coated Silica + 0.1% | 7341 | 543 | 11 |
| D-sorbitol | | | |
| 1.0% Ceria-coated Silica + 0.1% | 7147 | 722 | 20 |
| D-sorbitol + 20 ppm Picolinic | | | |
| Acid | | | |
| 1.0% Ceria-coated Silica + 0.1% | 6840 | 863 | 533 |
| D-sorbitol + 200 ppm Picolinic | | | |
| Acid | | | |

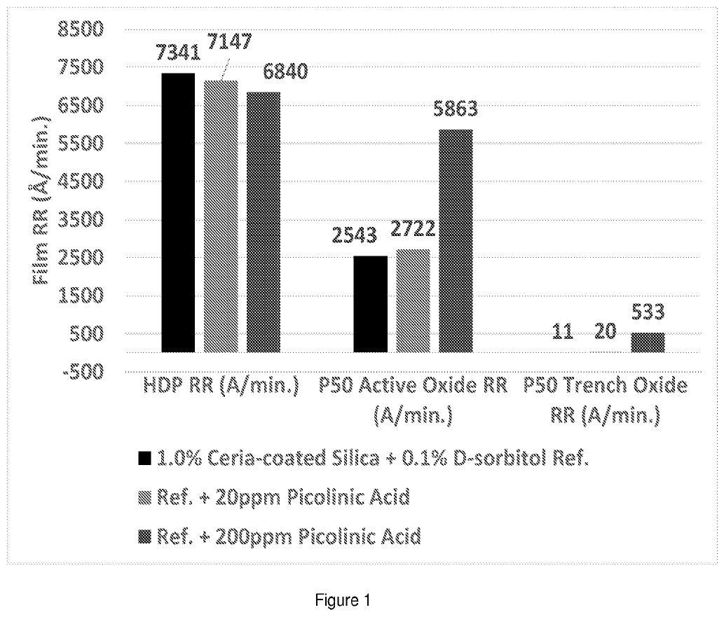

The removal rates (RR at Å/min) for different films were tested. The effects of chemical additive picolinic acid on the film removal rates and Pitch 50 μm trench oxide removal rates and active oxide removal rates were observed and listed in Table 1 and depicted in FIG. 1.

The removal rates (RR at Å/min) for different films were tested. The effects of chemical additive picolinic acid on the film removal rates and Pitch 50 μm trench oxide removal rates and active oxide removal rates were observed and listed in Table 1 and depicted in FIG. 1.

P1 oxide polishing step conditions were: Dow's IC1010 pad at 3.7 psf DF with table/head speed at 87/93 and ex-situ conditioning.

As the results shown in Table 1 and FIG. 1, the addition of picolinic acid in the polishing composition effectively boosted pitch 50 μm feature trench oxide removal rates while still afforded high HDP film removal rates, and thus increased patterned wafer oxide trench removal rates.

### Example 2

In Example 2, the polishing compositions used for oxide P2 step (STI P2 CMP step uses relative low oxide film removal rates which is also the step being used in STI CMP process to polish oxide patterned wafers.) polishing were shown in Table 2. The reference sample was made using 0.2 wt. % ceria-coated silica plus very low concentration of biocide and 0.15 wt. % D-sorbitol. The second chemical additive, picolinic acid was used at 0.002 wt. % in the testing sample.

All reference sample and testing sample had same pH values at around 5.35.

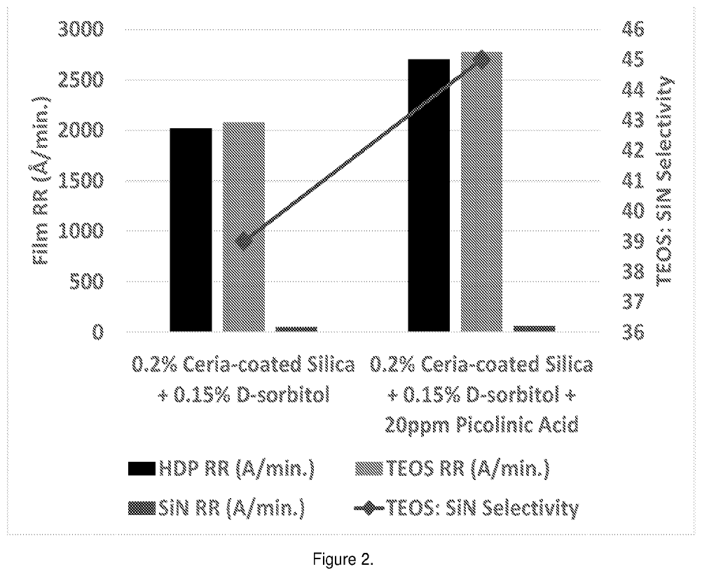

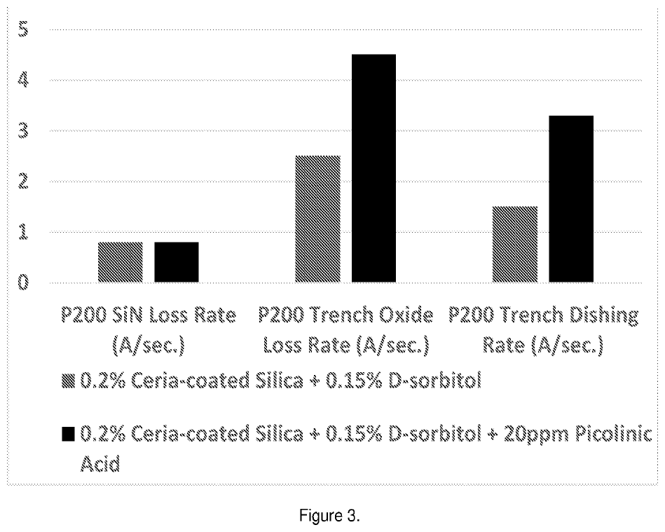

The removal rates (RR at Å/min) for different films were tested. The effects of chemical additive picolinic acid on the film removal rates and TEOS:SiN selectivity were observed and listed in Table 2 and depicted in FIG. 2.

TABLE 2
Effects of Picolinic Acid on Film
RR (A/min.) & TEOS:SiN Selectivity

| | HDP | TEOS | SiN | |
|---|---|---|---|---|
| | RR | RR | RR | TEOS:SiN |
| Compositions | (A/min.) | (A/min.) | (A/min.) | Selectivity |
| 0.2% Ceria-coated | 2022 | 2078 | 53 | 39:1 |
| Silica + 0.15% D- | | | | |
| sorbitol | | | | |
| 0.2% Ceria-coated | 2704 | 2776 | 62 | 45:1 |
| Silica + 0.15% D- | | | | |
| sorbitol + 20 ppm | | | | |
| Picolinic Acid | | | | |

As the results shown in Table 2 and FIG. 2, the addition of picolinic acid in the polishing composition effectively boosted TEOS and HDP film removal rates and increased the selectivity of TEOS:SiN as well.

Thus, the polishing compositions provided the boosted TEOS and HDP film removal rates and high Oxide:SiN selectivity.

The polishing conditions for P2 oxide polishing were: Dow's IC1010 pad, 2.7 psi down force with table/head speeds at 86/85, and with 100% insitu conditioning.

The effects of the chemical additive, picolinic acid, in P2 step polishing composition on oxide trench dishing rates, SiN film loss rate and the ratio of oxide trench loss vs blanket film removal rates were tested. The results were listed in Table 3 and depicted in FIG. 3.

TABLE 3
Effects of Picolinic Acid on Oxide Trench Dishing Rate etc.

| | | P200 | | |
|---|---|---|---|---|
| | P200 | Trench | P200 | P200 |
| | SiN | Oxide | Trench | Trench |
| | Loss | Loss | Dishing | Oxide Loss |
| | Rate | Rate | Rate | Rate/Blanket |
| Compositions | (A/sec.) | (A/sec.) | (A/sec.) | Film Rate |
| 0.2% Ceria-coated Silica + | 0.8 | 2.5 | 1.5 | 0.07 |
| 0.15% D-sorbitol | | | | |
| 0.2% Ceria-coated Silica + | 0.8 | 4.5 | 3.3 | 0.10 |
| 0.15% D-sorbitol + 20 ppm | | | | |
| Picolinic Acid | | | | |

As the results shown in Table 3 and FIG. 3, the addition of picolinic acid in the polishing composition showed no effects on P200 SiN loss removal rates, and still maintained relative low trench oxide loss rate and oxide trench dishing rate.

### Example 3

In Example 3, the polishing compositions used for oxide P2 step polishing were shown in Table 4. The reference sample was made using 0.2 wt. % ceria-coated silica plus very low concentration of biocide and 0.28 wt. % maltitol. The second chemical additive, picolinic acid was used at 0.0075 wt. % in the testing sample. All reference sample and testing sample have same pH values at around 5.35.

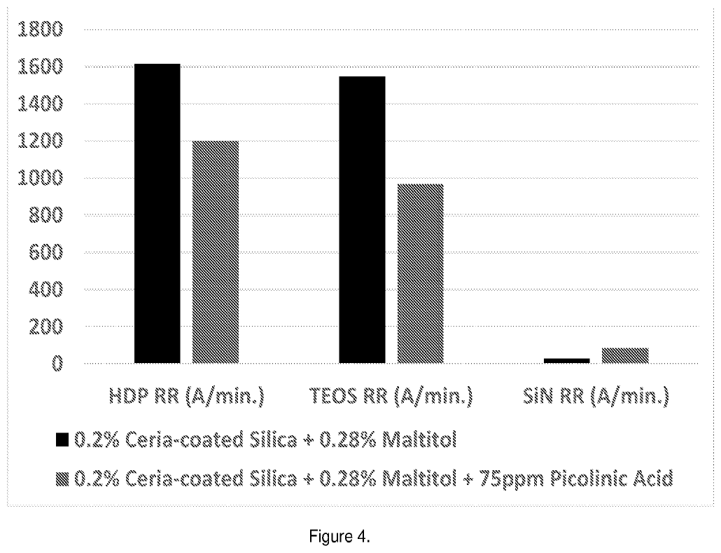

The removal rates (RR at Å/min) for different films were tested. The effects of chemical additive picolinic acid on the film removal rates and TEOS:SiN selectivity were observed and listed in Table 4 and depicted in FIG. 4.

The polishing parts and conditions were: Dow's polishing pad, 3M's conditioning disk, 2.0 psi DF, ex-situ conditioning and with 50/48 rpm table/head speeds.

TABLE 4
Effects of Picolinic Acid on Film
RR (A/min.) & TEOS:SiN Selectivity

| | HDP | TEOS | SiN | |
|---|---|---|---|---|
| | RR | RR | RR | TEOS:SiN |
| Compositions | (A/min.) | (A/min.) | (A/min.) | Selectivity |
| 0.2% Ceria-coated | 1614 | 1547 | 29 | 53:1 |
| Silica + 0.28% | | | | |
| Maltitol | | | | |
| 0.2% Ceria-coated | 1200 | 967 | 86 | 11:1 |
| Silica + 0.28% | | | | |
| Maltitol + 75 ppm | | | | |
| Picolinic Acid | | | | |

As the results shown in Table 4 and FIG. 4, the addition of the chemical additive, picolinic acid, in the polishing composition reduced TEOS and HDP film removal rates, thus, reduced TEOS; SiN selectivity.

### Example 4

In Example 4, the polishing compositions used for oxide P2 step polishing were shown in Table 5. The reference sample was made using 0.2 wt. % ceria-coated silica plus very low concentration of biocide and 0.28 wt. % maltitol at pH 5.35. The second chemical additive, picolinic acid was used at 0.0075 wt. % and with different pH conditions in the testing samples.

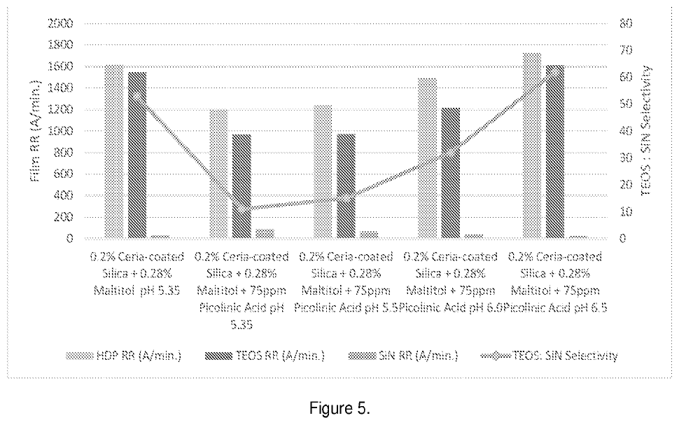

The removal rates (RR at Å/min) for different films were tested. The effects of chemical additive picolinic acid at different pH conditions on the film removal rates and TEOS:SiN selectivity were observed and listed in Table 5 and depicted in FIG. 5.

The polishing parts and conditions were: Dow's polishing pad, 3M's conditioning disk, 2.0 psi DF, ex-situ conditioning and with 50/48 rpm table/head speeds.

As the results shown in Table 5 and FIG. 5, with the same concentrations of second type of chemical additive picolinic acid at different pH conditions, both HDP and TEOS film removal rates were increased gradually as the pH of the polishing compositions increased.

TABLE 5
Effects of Picolinic Acid at Different pH
on Film RR (A/min.) & TEOS:SiN Selectivity

| | HDP RR | TEOS RR | SiN RR | TEOS:SiN |
|---|---|---|---|---|
| Compositions | (A/min.) | (A/min.) | (A/min.) | Selectivity |
| 0.2% Ceria-coated Silica + 0.28% | 1614 | 1547 | 29 | 53:1 |
| Maltitol pH 5.35 | | | | |
| 0.2% Ceria-coated Silica + 0.28% | 1200 | 967 | 86 | 11:1 |
| Maltitol + 75 ppm Picolinic Acid pH | | | | |
| 5.35 | | | | |
| 0.2% Ceria-coated Silica + 0.28% | 1239 | 971 | 65 | 15:1 |
| Maltitol + 75 ppm Picolinic Acid pH | | | | |
| 5.5 | | | | |
| 0.2% Ceria-coated Silica + 0.28% | 1492 | 1212 | 38 | 32:1 |
| Maltitol + 75 ppm Picolinic Acid pH | | | | |
| 6.0 | | | | |
| 0.2% Ceria-coated Silica + 0.28% | 1724 | 1612 | 26 | 62:1 |
| Maltitol + 75 ppm Picolinic Acid pH | | | | |
| 6.5 | | | | |

The SiN film removal rates were gradually decreased as the pH of the polishing compositions increased. TEOS:SiN selectivity were increased gradually as the pH of the polishing compositions increased. 62:1 TEOS:SiN selectivity was achieved at pH 6.5.

TABLE 6
Effects of Picolinic Acid at Different
pH on Oxide Trench Loss (A/sec.)

| | P100 | P200 | P1000 |
|---|---|---|---|
| | Trench | Trench | Trench |
| | Loss Rate | Loss Rate | Loss Rate |
| Compositions | (A/sec.) | (A/sec.) | (A/sec.) |
| 0.2% Ceria-coated Silica + 0.28% | 1.0 | 1.4 | 1.4 |
| Maltitol pH 5.35 | | | |
| 0.2% Ceria-coated Silica + 0.28% | 5.4 | 6.3 | 13.0 |
| Maltitol + 75 ppm Picolinic Acid | | | |
| pH 5.35 | | | |
| 0.2% Ceria-coated Silica + 0.28% | 4.7 | 5.4 | 11.8 |
| Maltitol + 75 ppm Picolinic Acid | | | |
| pH 5.5 | | | |
| 0.2% Ceria-coated Silica + 0.28% | 2.2 | 2.4 | 3.0 |
| Maltitol + 75 ppm Picolinic Acid | | | |
| pH 6.0 | | | |
| 0.2% Ceria-coated Silica + 0.28% | 1.6 | 2.1 | 2.7 |
| Maltitol + 75 ppm Picolinic Acid | | | |
| pH 6.5 | | | |

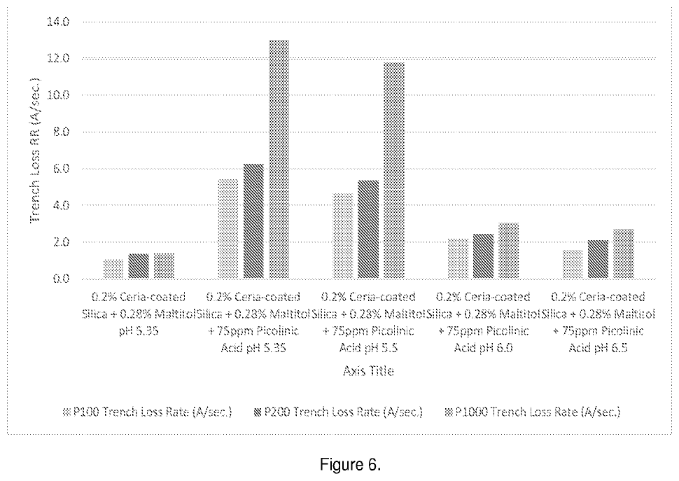

The effects of chemical additive picolinic acid at same concentrations and at different pH conditions on the oxide trench loss rates were observed and listed in Table 6 and depicted in FIG. 6.

The polishing parts and conditions were: Dow's polishing pad, 3M's conditioning disk, 2.0 psi DF, ex-situ conditioning and with 50/48 rpm table/head speeds.

As the results shown in Table 6 and FIG. 6, with the same concentrations of second type of chemical additive picolinic acid at different pH conditions, the oxide trench loss rate at three different sized pitches were reduced gradually as the pH of the polishing compositions increased.

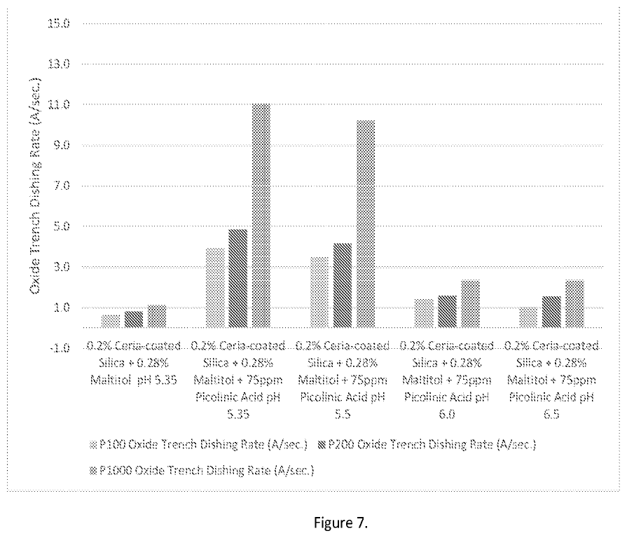

The effects of chemical additive picolinic acid at same concentrations and at different pH conditions on the oxide trench dishing rates were observed and listed in Table 7 and depicted in FIG. 7.

The polishing parts and conditions were: Dow's polishing pad, 3M's conditioning disk, 2.0 psi DF, ex-situ conditioning and with 50/48 rpm table/head speeds.

TABLE 7
Effects of Picolinic Acid at Different pH
on Oxide Trench Dishing Rate (A/sec.)

| | P100 | P200 | P1000 |
|---|---|---|---|
| | Oxide | Oxide | Oxide |
| | Trench | Trench | Trench |
| | Dishing | Dishing | Dishing |
| | Rate | Rate | Rate |
| Compositions | (A/sec.) | (A/sec.) | (A/sec.) |
| 0.2% Ceria-coated Silica + 0.28% | 0.6 | 0.8 | 1.1 |
| Maltitol pH 5.35 | | | |
| 0.2% Ceria-coated Silica + 0.28% | 3.9 | 4.9 | 11.1 |
| Maltitol + 75 ppm Picolinic Acid pH | | | |
| 5.35 | | | |
| 0.2% Ceria-coated Silica + 0.28% | 3.5 | 4.2 | 10.2 |
| Maltitol + 75 ppm Picolinic Acid pH | | | |
| 5.5 | | | |
| 0.2% Ceria-coated Silica + 0.28% | 1.4 | 1.6 | 2.4 |
| Maltitol + 75 ppm Picolinic Acid pH | | | |
| 6.0 | | | |
| 0.2% Ceria-coated Silica + 0.28% | 1.0 | 1.6 | 2.4 |
| Maltitol + 75 ppm Picolinic Acid pH | | | |
| 6.5 | | | |

As the results shown in Table 7 and FIG. 7, with the same concentrations of second type of chemical additive picolinic acid at different pH conditions, the oxide trench dishing rates at three different sized pitches were reduced gradually as the pH of the polishing compositions increased.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A chemical mechanical polishing composition comprising:
0.05 wt. % to 10 wt. % ceria-coated inorganic oxide particles;
0.0005 wt. % to 1.0 wt. % nitrogen containing organic aromatic or pyridine ring molecule having one carboxylic acid group, one carboxylate salt group, or one carboxylate ester group;
0.001 wt. % to 1.0 wt. % non-ionic organic molecule having multi hydroxyl functional groups;
water soluble solvent; and
optionally
biocide; and
pH adjuster;
wherein
the nitrogen containing organic aromatic or pyridine ring molecule having one carboxylic acid group, one carboxylate salt group, or one carboxylate ester group has a general molecular structure of: 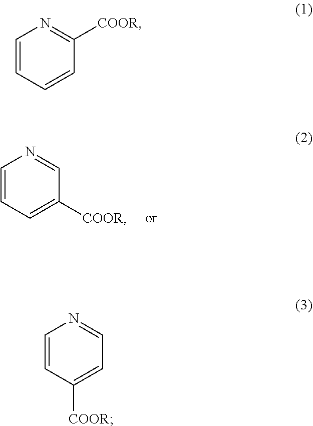
wherein R can be hydrogen atom, a positive metal ion M⁺ selected from the group consisting of sodium, potassium, and ammonium ion, or an alkyl group CₙH₂ₙ₊₁, n is 1 to 6;
the non-ionic organic molecule with multi hydroxyl functional groups has a general molecular structure selected from the group consisting of:
(a) 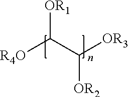
wherein n is selected from 2 to 12;
R1, R2, R3, and R4 of R groups can be the same or different atoms or functional groups; and
each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least four or more of R groups are all hydrogen atoms;
(b) 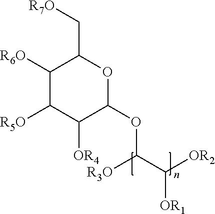
wherein n is selected from 1 to 12;
R1, R2, R3, R4, R5, R6, and R7 of R groups can be the same or different atoms or functional groups; and each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein at least four or more of R groups are hydrogen atoms;
and combinations thereof;
and
the composition has a pH of 4 to 9.

2. The chemical mechanical polishing composition of claim 1, wherein the ceria-coated inorganic oxide particles are selected from the group consisting of ceria-coated colloidal silica, ceria-coated alumina, ceria-coated titania, ceria-coated zirconia particles and combinations thereof; and
the water soluble solvent is selected from the group consisting of deionized (DI) water, distilled water, alcoholic organic solvent, and combinations thereof.

3. (canceled)

4. (canceled)

5. (canceled)

6. (canceled)

7. The chemical mechanical polishing composition of claim 1, wherein R in the —COOR group of the nitrogen containing organic aromatic or pyridine ring molecule is hydrogen atom, and the —COOH group can be attached to carbon atom positioned at −2, −3, or 4 in the ring as shown below: 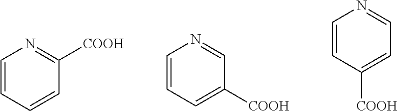 [SMILES: O=C(O)c1ccccn1 ; O=C(O)c1cccnc1 ; O=C(O)c1ccncc1]
2-Picolinic Acid, 3-Pyridinrcarboxylic Acid, and 4-Pyridinrcarboxylic Acid.

8. (canceled)

9. (canceled)

10. (canceled)

11. The chemical mechanical polishing composition of claim 1, wherein the non-ionic organic molecule with multi hydroxyl functional groups is selected from the group consisting of 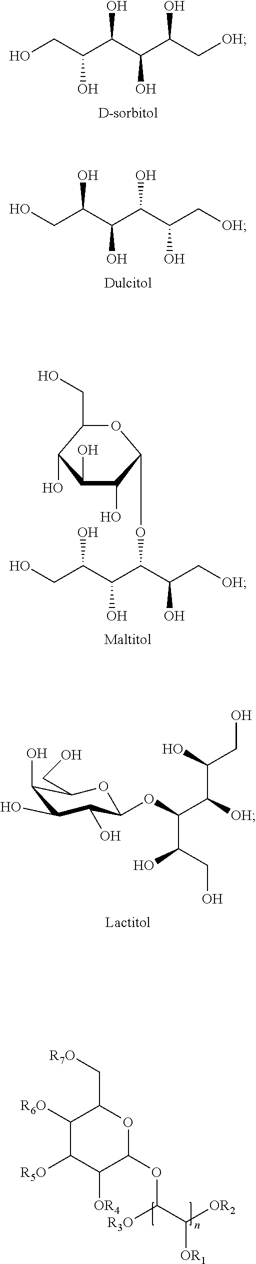
wherein n is selected from 1 to 12, or from 2 to 6; and
R1, R2, R3, R4, R5, R6, and R7 are all hydrogen atoms;
and combinations thereof.

12. (canceled)

13. (canceled)

14. (canceled)

15. (canceled)

16. The chemical mechanical polishing composition of claim 1, wherein the composition comprises ceria-coated colloidal silica particles; at least one selected from the group consisting of lactitol, Maltitol, Dulcitol, and D-sorbitol; pyridine ring molecule with one carboxylic acid, carboxylate salt, or carboxylate ester connected to carbon atom positioned at −2, −3, or −4 in the pyridine ring; and water.

17. The chemical mechanical polishing composition of claim 1, wherein the composition comprises ceria-coated colloidal silica particles; at least one selected from the group consisting of lactitol, Maltitol, Dulcitol, and D-sorbitol; and at least one selected from the group consisting of 2-Picolinic Acid, 3-Pyridinrcarboxylic Acid, and 4-Pyridinrcarboxylic Acid.

18. (canceled)

19. (canceled)

20. The chemical mechanical polishing composition of claim 1, further comprises at least one selected from the group consisting of from 0.0005 wt. % to 0.025 wt. % of the biocide having active ingredients of 5-chloro-2-methyl-4-isothiazolin-3-one and 2-methyl-4-isothiazolin-3-one; from 0.01 wt. % to 0.5 wt. % of the pH adjuster selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

21. A method of chemical mechanical polishing (CMP) a semiconductor substrate having at least one surface comprising a silicon oxide film, comprising providing the semiconductor substrate;
providing a polishing pad;
providing a chemical mechanical polishing composition comprising:
0.05 wt. % to 10 wt. % ceria-coated inorganic oxide particles selected from the group consisting of ceria-coated colloidal silica, ceria-coated alumina, ceria-coated titania, ceria-coated zirconia particles and combinations thereof;
0.0005 wt. % to 1.0 wt. % nitrogen containing organic aromatic or pyridine ring molecule having one carboxylic acid group, one carboxylate salt group, or one carboxylate ester group;
0.001 wt. % to 1.0 wt. % non-ionic organic molecule having multi hydroxyl functional groups;
water soluble solvent selected from the group consisting of deionized (DI) water, distilled water, alcoholic organic solvent, and combinations thereof; and
optionally
biocide; and
pH adjuster;
wherein
the nitrogen containing organic aromatic or pyridine ring molecule having one carboxylic acid group, one carboxylate salt group, or one carboxylate ester group has a general molecular structure of: 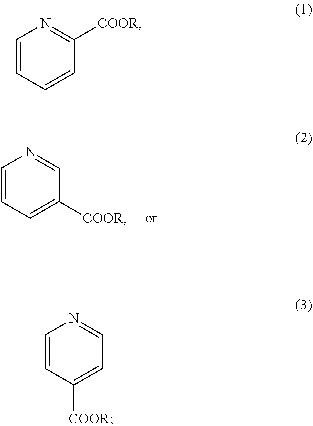
wherein R can be hydrogen atom, a positive metal ion M⁺ selected from the group consisting of sodium, potassium, and ammonium ion, or an alkyl group CₙH₂ₙ₊₁, n is 1 to 6;
the non-ionic organic molecule with multi hydroxyl functional groups has a general molecular structure selected from the group consisting of:
(a) 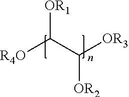
wherein n is selected from 2 to 12;
R1, R2, R3, and R4 of R groups can be the same or different atoms or functional groups; and each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least four or more of R groups are all hydrogen atoms;
(b) 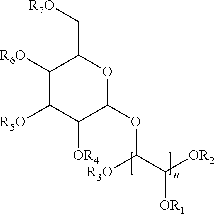
wherein n is selected from 1 to 12;
R1, R2, R3, R4, R5, R6, and R7 of R groups can be the same or different atoms or functional groups; and each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof;
wherein at least four or more of R groups are hydrogen atoms;
and combinations thereof;
and
the composition has a pH of 4 to 9;
contacting the at least one surface of the semiconductor substrate with the polishing pad and the chemical mechanical polishing composition; and
polishing the at least one surface comprising the silicon oxide film;
wherein the silicon oxide film is selected from the group consisting of Chemical vapor deposition (CVD), Plasma Enhance CVD (PECVD), High Density Deposition CVD (HDP), or spin on silicon oxide film.

22. (canceled)

23. (canceled)

24. The method of claim 21; wherein the semiconductor substrate further having at least one surface comprising a silicon nitride film; and removal selectivity of silicon oxide: silicon nitride is greater than 30 or greater than 50.

25. A system of chemical mechanical polishing (CMP) a semiconductor substrate having at least one surface comprising an oxide film, comprising
a. the semiconductor substrate;
b. chemical mechanical polishing composition comprising:
0.05 wt. % to 10 wt. % ceria-coated inorganic oxide particles selected from the group consisting of ceria-coated colloidal silica, ceria-coated alumina, ceria-coated titania, ceria-coated zirconia particles and combinations thereof;
0.0005 wt. % to 1.0 wt. % nitrogen containing organic aromatic or pyridine ring molecule having one carboxylic acid group, one carboxylate salt group, or one carboxylate ester group;
0.001 wt. % to 1.0 wt. % non-ionic organic molecule having multi hydroxyl functional groups;
water soluble solvent selected from the group consisting of deionized (DI) water, distilled water, alcoholic organic solvent, and combinations thereof; and
optionally
biocide; and
pH adjuster;
wherein
the nitrogen containing organic aromatic or pyridine ring molecule having one carboxylic acid group, one carboxylate salt group, or one carboxylate ester group has a general molecular structure of: 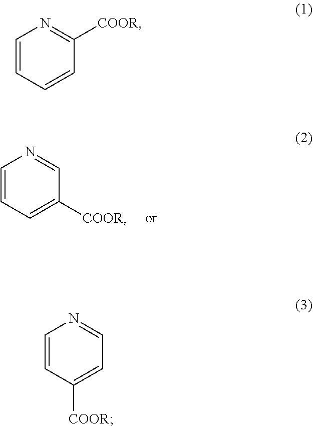
wherein R can be hydrogen atom, a positive metal ion M⁺ selected from the group consisting of sodium, potassium, and ammonium ion, or an alkyl group CₙH₂ₙ₊₁, n is 1 to 6;
the non-ionic organic molecule with multi hydroxyl functional groups has a general molecular structure selected from the group consisting of:
(a) 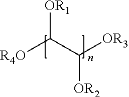
wherein n is selected from 2 to 12;
R1, R2, R3, and R4 of R groups can be the same or different atoms or functional groups; and each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof; wherein, at least four or more of R groups are all hydrogen atoms;
(b) 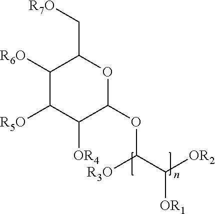
wherein n is selected from 1 to 12;
R1, R2, R3, R4, R5, R6, and R7 of R groups can be the same or different atoms or functional groups; and each is independently selected from the group consisting of hydrogen, an alkyl group CₙH₂ₙ₊₁, n is from 1 to 6; alkoxy, organic group with one or more hydroxyl groups, substituted organic sulfonic acid, substituted organic sulfonic acid salt, substituted organic carboxylic acid, substituted organic carboxylic acid salt, organic carboxylic acid ester, organic amine groups, and combinations thereof;
wherein at least four or more of R groups are hydrogen atoms;
and combinations thereof;
and
the composition has a pH of 4 to 9;
c. a polishing pad;
wherein the at least one surface comprising the silicon oxide film is in contact with the polishing pad and the chemical mechanical polishing composition; and the silicon oxide film is selected from the group consisting of Chemical vapor deposition (CVD), Plasma Enhance CVD (PECVD), High Density Deposition CVD (HDP), or spin on silicon oxide film.

26. (canceled)

27. (canceled)

28. The system of claim 25; wherein the semiconductor substrate further having at least one surface comprising a silicon nitride film, wherein the at least one surface comprising a silicon nitride film is in contact with the polishing pad and the chemical mechanical polishing composition; and removal selectivity of silicon oxide: silicon nitride is greater than 30, or greater than 50; when the at least surface comprising a silicon oxide film and the at least one surface comprising a silicon nitride film are polished with the polishing pad and the chemical mechanical polishing composition.

29. The method of claim 21, wherein R in the —COOR group of the nitrogen containing organic aromatic or pyridine ring molecule is hydrogen atom, and the —COOH group can be attached to carbon atom positioned at −2, −3, or 4 in the ring as shown below: 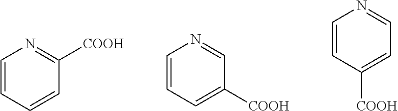 [SMILES: O=C(O)c1ccccn1 ; O=C(O)c1cccnc1 ; O=C(O)c1ccncc1]
2-Picolinic Acid, 3-Pyridinrcarboxylic Acid, and 4-Pyridinrcarboxylic Acid.

30. The method of claim 21, wherein the non-ionic organic molecule with multi hydroxyl functional groups is selected from the group consisting of 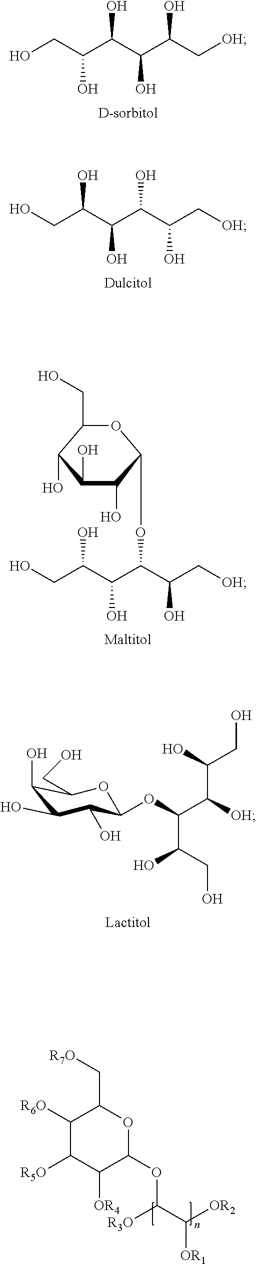
wherein
n is selected from 1 to 5,000, preferably from 1 to 100, more preferably from 1 to 12, and most preferably from 2 to 6; and
R1, R2, R3, R4, R5, R6, and R7 are all hydrogen atoms and combinations thereof;
and combinations thereof.

31. The method of claim 21, wherein the chemical mechanical polishing composition comprises ceria-coated colloidal silica particles; at least one selected from the group consisting of lactitol, Maltitol, Dulcitol, and D-sorbitol; and at least one selected from the group consisting of 2-Picolinic Acid, 3-Pyridinrcarboxylic Acid, and 4-Pyridinrcarboxylic Acid.

32. The method of claim 21, wherein the chemical mechanical polishing composition further comprises at least one selected from the group consisting of from 0.0005 wt. % to 0.025 wt. % of the biocide having active ingredients of 5-chloro-2-methyl-4-isothiazolin-3-one and 2-methyl-4-isothiazolin-3-one; from 0.01 wt. % to 0.5 wt. % of the pH adjuster selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.

33. The system of claim 25, wherein R in the —COOR group of the nitrogen containing organic aromatic or pyridine ring molecule is hydrogen atom, and the —COOH group can be attached to carbon atom positioned at −2, −3, or 4 in the ring as shown below: 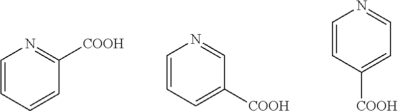 [SMILES: O=C(O)c1ccccn1 ; O=C(O)c1cccnc1 ; O=C(O)c1ccncc1]
2-Picolinic Acid, 3-Pyridinrcarboxylic Acid, and 4-Pyridinrcarboxylic Acid.

34. The system of claim 25, wherein the non-ionic organic molecule with multi hydroxyl functional groups is selected from the group consisting of 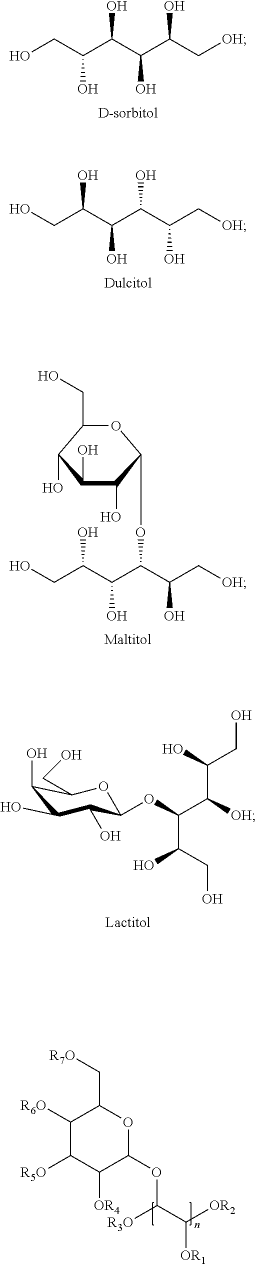
wherein
n is selected from 1 to 5,000, preferably from 1 to 100, more preferably from 1 to
12, and most preferably from 2 to 6; and
R1, R2, R3, R4, R5, R6, and R7 are all hydrogen atoms and combinations thereof;
and combinations thereof.

35. The system of claim 25, wherein the chemical mechanical polishing composition comprises ceria-coated colloidal silica particles; at least one selected from the group consisting of lactitol, Maltitol, Dulcitol, and D-sorbitol; and at least one selected from the group consisting of 2-Picolinic Acid, 3-Pyridinrcarboxylic Acid, and 4-Pyridinrcarboxylic Acid.

36. The system of claim 25, wherein the chemical mechanical polishing composition further comprises at least one selected from the group consisting of from 0.0005 wt. % to 0.025 wt. % of the biocide having active ingredients of 5-chloro-2-methyl-4-isothiazolin-3-one and 2-methyl-4-isothiazolin-3-one; from 0.01 wt. % to 0.5 wt. % of the pH adjuster selected from the group consisting of nitric acid, hydrochloric acid, sulfuric acid, phosphoric acid, other inorganic or organic acids, and mixtures thereof for acidic pH conditions; or selected from the group consisting of sodium hydride, potassium hydroxide, ammonium hydroxide, tetraalkyl ammonium hydroxide, organic quaternary ammonium hydroxide compounds, organic amines, and combinations thereof for alkaline pH conditions.
